(19) United States
(12) Patent Application Publication
(10) Pub. No.: US 2009/0152243 A1
(43) Pub. Date: Jun. 18, 2009

(54) PLASMA PROCESSING APPARATUS AND METHOD THEREOF

(75) Inventors: Takahiro Horiguchi, Kanagawa (JP); Shinsuke Oka, Kanagawa (JP); Masaki Hirayama, Miyagi (JP)

Correspondence Address: OBLON, SPIVAK, MCCLELLAND MAIER & NEUSTADT, P.C., 1940 DUKE STREET, ALEXANDRIA, VA, 22314, US

(73) Assignees: Tokyo Electron Limited, Minato-ku, Tokyo (JP); Tohoku University, Sendai-shi, Miyagi (JP)

(21) Appl. No.: 12/088,440

(22) PCT Filed: Sep. 27, 2006
(86) PCT No.: PCT/JP2006/319138

§ 371 Date: Mar. 28, 2008

(30) Foreign Application Priority Data
Sep. 30, 2005 (JP) 2005-289249

(51) Int. Cl. C23F 1/00; C23C 16/513; C23F 1/08; C23C 16/511

(52) U.S. Cl. 216/69; 118/708; 156/345.24; 427/575

(57) ABSTRACT

[Problem] To provide a plasma processing apparatus and a method thereof, which is capable of generating plasma evenly on the lower surface of a dielectric.

[Means for Solving] A plasma processing apparatus 1, in which microwave is propagated into a dielectric 32 provided on an upper surface of a processing chamber 4 via plural slots 70 formed on a lower surface of a waveguide 35 and a processing gas supplied in the processing chamber 4 is made into plasma using electric field energy of an electromagnetic field formed on the surface of the dielectric to perform plasma processing on a substrate G. The plasma processing apparatus 1, concave portions 80a to 80g having different depth are formed on a lower surface of dielectric 32. Further, the depths of the respective concave portions 80a to 80g are made different to control a plasma generation on the lower surface of the dielectric 32.

### TECHNICAL FIELD

The present invention relates to a plasma processing apparatus and a method thereof, capable of generating plasma to perform a treatment such as forming a film on a substrate.

### BACKGROUND ART

In a process of manufacturing an LCD device and the like, an apparatus for generating plasma in a processing chamber using microwaves and performing a CVD treatment or a etching treatment on an LCD substrate is used. As such a plasma processing apparatus, an apparatus having plural waveguides in an upper portion of a processing chamber is known (for example, see Patent Documents 1 and 2). On a lower surface of the waveguides, plural slots are opened at even intervals and a plate-like dielectric is provided along the lower surface of the waveguides. Microwaves are propagated on the surface of the dielectric via the slots and a processing gas supplied in the processing chamber is made into plasma using energy of the microwave (electromagnetic field). Further, in purpose of generating plasma evenly on the lower surface of the dielectric, an apparatus, in which concave portions and convex portions are formed on the lower surface of the dielectric, has been disclosed (for example, see Patent Document 3).

### [Patent Document 1] Japanese Patent Application Laid-Open No. 2004-200646

### [Patent Document 2] Japanese Patent Application Laid-Open No. 2004-152876

### [Patent Document 3] Japanese Patent Application Laid-Open No. 2003-142457

### DISCLOSURE OF THE INVENTION

### Problems to Be Solved by the Invention

As the size of substrates is getting larger, processing apparatus thereof has been getting larger, and accordingly, the size of a dielectric disposed in an upper portion of a processing chamber has also been increased. However, it is very difficult to generate plasma evenly on the entire lower surface of such a large dielectric and efficient stable plasma processing has not been attained. Particularly on the lower surface of the dielectric, the plasma generation strength differs at a position close to a slot and a position separated from the slot. Further, the dielectrics are supported by a supporting member such as a beam made of aluminum, for example; however, at peripheral portion of the dielectric, standing waves are generated due to reflected waves reflected by the supporting member and thus it has been a problem that uneven plasma is generated due to undulations of large waves.

In view of this problem, an object of the present invention is to provide a plasma processing apparatus and a plasma processing method capable of generating plasma evenly on an entire lower surface of a dielectric.

### Means for Solving the Problems

In order to solve the above problem, the present invention provides a plasma processing apparatus, in which microwave is propagated into a dielectric provided on an upper surface of a processing chamber through plural slots formed on a lower surface of a waveguide and a processing gas supplied into the processing chamber is made into plasma using an electric field energy of an electromagnetic field formed on a surface of the dielectric. One or more plural concave portions are formed on the lower surface of the dielectric and the depth of the concave portion is changed corresponding to a distance from the slots.

On the lower surface of the dielectric, the concave portions can be formed at a position close to the slots and at a position separate from the slots and the depth of the concave portion formed separately from the slot can be made deeper than the depth of the concave portion formed close to the slot.

Plural dielectrics can be provided on the upper surface of the processing chamber and the plural concave portions having different depths can be formed on the lower surfaces of the respective dielectrics. In this case, the dielectric can be formed in a rectangular shape having a length in a longitudinal direction longer than a wavelength of the microwave propagated in the dielectric and a length in a width direction shorter than the wavelength of the microwave propagated in the dielectric. Further, the dielectric can be provided to cross over two slots and a concave portion having a deepest depth can be formed between the two slots. In this case, the concave portion placed in the middle between the two slots can have a deepest depth. Or, between the two slots, the concave portion placed between the concave portion placed in the middle and the concave portions placed closest to the slots can have a deepest depth. Further, on the lower surface of the dielectric, among the plural concave portions formed as being aligned along the longitudinal direction, the depths of the concave portions placed at the both ends can be made shallower than the depths of the concave portions placed interior to the slots.

Around the plural dielectrics, one, two or more gas ejecting ports supplying a processing gas into the processing chamber can be provided. In this case, the gas ejecting port can be provided to a supporting member supporting the plural dielectrics.

Around the plural dielectrics, one, two or more first gas ejecting ports supplying a first processing gas into the processing chamber and one, two or more second gas ejecting ports supplying a second processing gas into the processing chamber can be provided. In this case, one of the first ejecting port and the second ejecting port can be disposed lower than the other of the first ejecting port and the second ejecting port.

The present invention also provides a plasma processing method, in which plasma processing is performed on the substrate by propagating microwave into a dielectric placed on an upper surface of a processing chamber through plural slots formed on a lower surface of a waveguide and making a processing gas supplied in the processing chamber into plasma using an electric field energy of an electromagnetic field formed on a surface of the dielectric. Plural concave portions are formed on a lower surface of the dielectric and the concave portions are made to have different depths to control the plasma generation on the lower face of the dielectric.

### EFFECT OF THE INVENTION

According to the present invention, since the plural concave portions are formed on the lower surface of the dielectric, a substantially vertical electric field is formed on an inner surfaces of the concave portions using an energy of microwaves propagated in the dielectric and plasma can efficiently be generated in a vicinity of the electric field. Further, it can be made stable where plasma is generated. In this case, the depths of the concave portions formed on the lower surface of the dielectric are made different from each other so that the strength of plasma generated at the concave portion placed close to the slot and the strength of plasma generated at the concave portion placed away from the slot can be equal. For example, on the lower surface of the dielectric, when concave portions are formed at a portion close to the slot and a position separated from the slot, the strength of the electric field formed by the energy of the microwaves propagated in the dielectric via the slot is reduced as being farther from the slot. In view of this matter, when the depth of the concave portion formed at a position separated from the slot is made deeper than the depth of the concave portion formed at a position close to the slot to provide the area of the inner surfaces of the concave portion wider than the area of the inner surface of the concave portion formed close to the slot, it becomes possible to prevent a reduction of the electric field reduction corresponding to the distance from the slot.

The plural dielectrics disposed on an upper surface of the processing chamber is formed in a rectangular shape having a length longer than the wavelength of the microwave propagated in the dielectric and a width shorter than the wavelength of the microwave propagated in the dielectric. With this structure, the propagation of the microwaves in dielectric is made to a single mode, in which a mode jump does not occur when the process condition is changed, so that it is possible to generate a stable plasma condition. On the other hand, at the ends of the dielectric in a longitudinal direction, which is longer than the wavelength of the microwave propagated in the dielectric, the intervals of the plural concave portions aligned along the longitudinal direction of the dielectric can be adjusted to suppress the surface waves and minimize the standing waves.

When the plural concave portions are placed aligned along the longitudinal direction of the rectangular dielectric as above, the concave portions at the longitudinal ends of the dielectric receives plasma of larger strength due to reflections of the surface waves by the supporting member which supports the dielectric. Thus, it is preferable that, among the concave portions formed along the longitudinal direction on the lower surface of the dielectric, the depths of the concave portions at the both ends are made shallower than the depths of the concave portions placed interior to the slots.

When the dielectric is provided so as to cross over two slots, a concave portion having deepest depth can be formed between the two slots. With this structure, the microwave from the slots is efficiently used for generating an electric field at the deepest concave portion and less microwave propagated into the dielectric from the slots turns back to the waveguide via the lots so that a cutoff phenomenon occurs and a generation of reflected waves is suppressed.

### BRIEF DESCRIPTION OF THE DRAWINGS

FIG. 1

A vertical sectional view showing a schematic configuration of a plasma processing apparatus according to an embodiment of the present invention.

FIG. 2

A bottom view of a lid.

FIG. 3

An enlarged vertical sectional view of the lid.

FIG. 4

An enlarged view of a dielectric seen from under the lid.

FIG. 5

A vertical sectional view of the dielectric taken along the line X-X line in FIG. 4.

FIG. 6

An explanatory view of an embodiment, in which a second gas ejecting port is disposed lower than a second ejecting port.

FIG. 7

A vertical sectional view of the dielectric taken along the line X-X line in FIG. 4 according to another embodiment.

FIG. 8

A vertical sectional view of the dielectric taken along the line X-X line in FIG. 4 according to another embodiment, in which the depth of concave portion that is not placed in the middle between two slots are made deepest.

FIG. 9

An enlarged view of the dielectric according to an embodiment, in which a single dielectric is disposed for every slot.

FIG. 10

A vertical sectional view of the dielectric taken along the X-X line in FIG. 9.

FIG. 11

A graph showing simulation results of an embodiment, the graph showing, for the respective concave portions, changes in average of maximum electric field strength per cycle in the respective concave portions when the depths of the concave portions, which are just under the slot, interior to the slot, and adjacent to the slot, are changed to 4 mm, 6 mm, and 8 mm.

FIG. 12

A graph showing simulation results of an embodiment, the graph showing, for the respective concave portions, changes in maximum electric field strength per cycle at the center of the respective portions, which are just under the slot, interior to the slot, and adjacent to the slot, are changed to 4 mm, 6 mm, and 8 mm.

FIG. 13

A graph showing simulation results of an embodiment, the graph showing averages of electric field strength in the respective concave portions and the uniformities of electric field strength in the respective concave portions with respect to the depth of the concave portion interior to the position just under the slots.

FIG. 14

A graph showing simulation results of an embodiment, the graph showing averages of electric field strength at the center of the respective concave portions and the uniformities of electric field strength at the center of the respective concave portions with respect to the depth of the concave portion interior to the position just under the slots.

### EXPLANATION OF CODES

G substrate
1 plasma processing apparatus
2 process vessel
3 lid
4 processing chamber
10 susceptor
11 power feeding part
12 heater
13 high-frequency power supply
14 matching device
15 high-voltage DC power supply
16 coil
17 AC power supply
20 lift plate
21 barrel unit
22 bellows
23 exhaust port
24 current plate
30 lid main body
31 slot antenna
32 dielectric
33 O-ring
35 rectangular waveguide
36 dielectric member
40 microwave feeder
41 Y branch pipe
45 top face
46 lift mechanism
50 cover member
51 guide part
52 lift part
55 guide rod
56 lift rod
57 nut
58 hole
60 guide
61 plate
62 rotation handle
70 slot
71 dielectric member
72 beam
80a, 80b, 80c, 80d, 80e, 80f, 80g concave portion
81 wall surface
85 gas ejecting port
90 gas pipe
91 cooling water pipe
95 processing gas supply source
100 argon gas supply source
101 silane gas supply source
102 hydrogen gas supply source
105 cooling water supply source

### BEST MODE FOR CARRYING OUT THE INVENTION

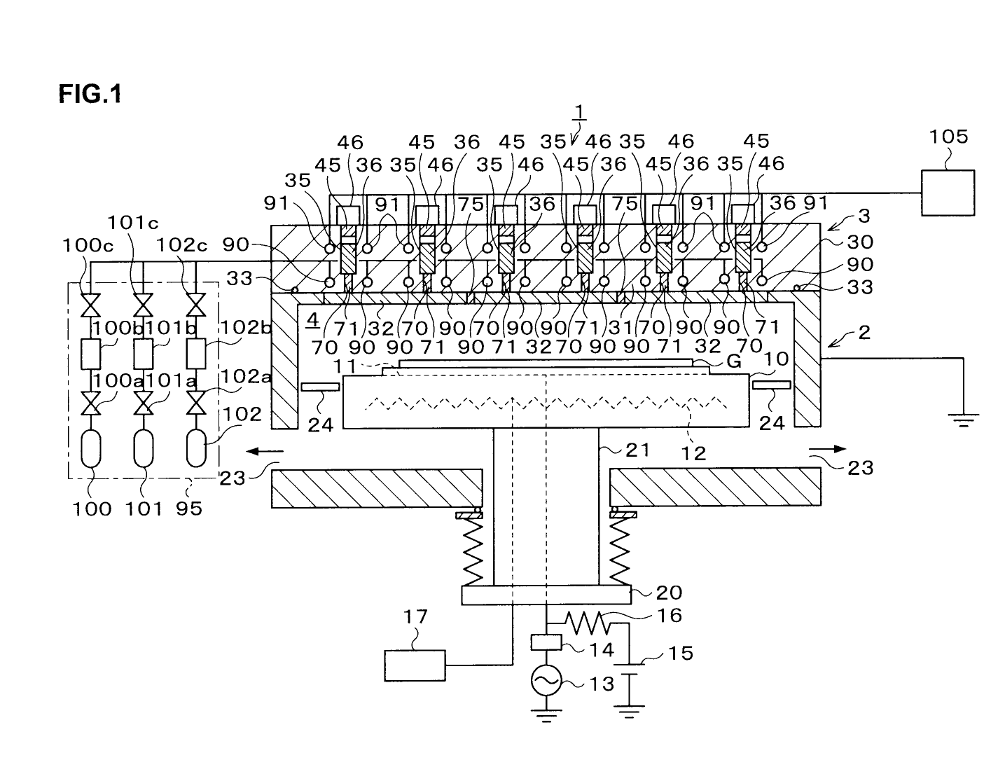

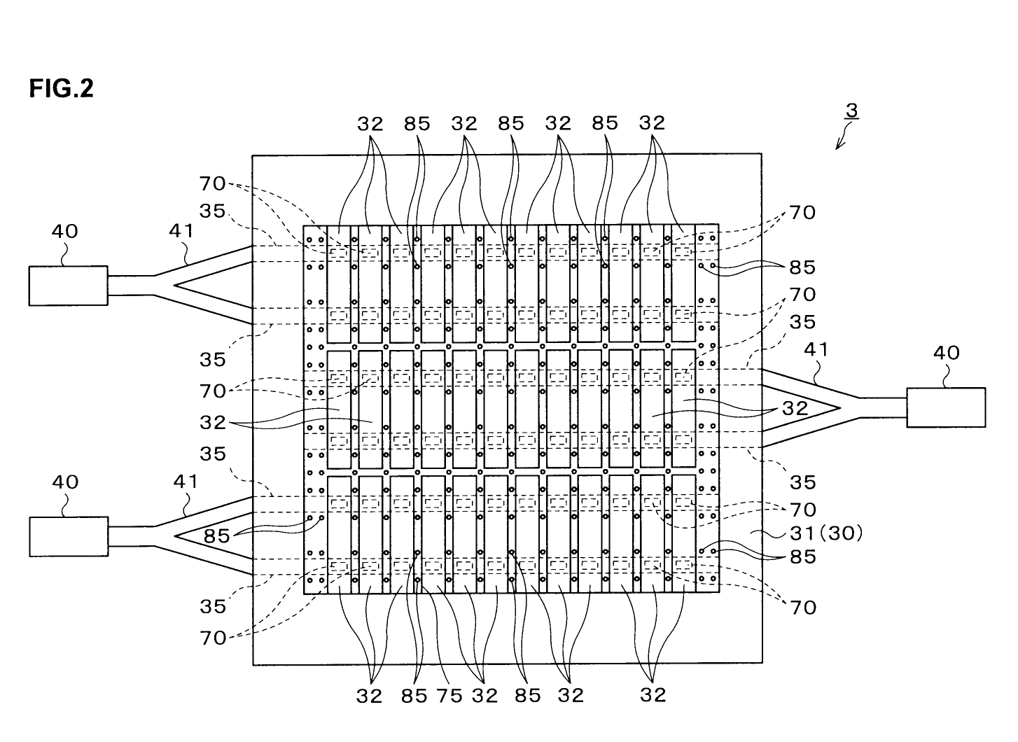

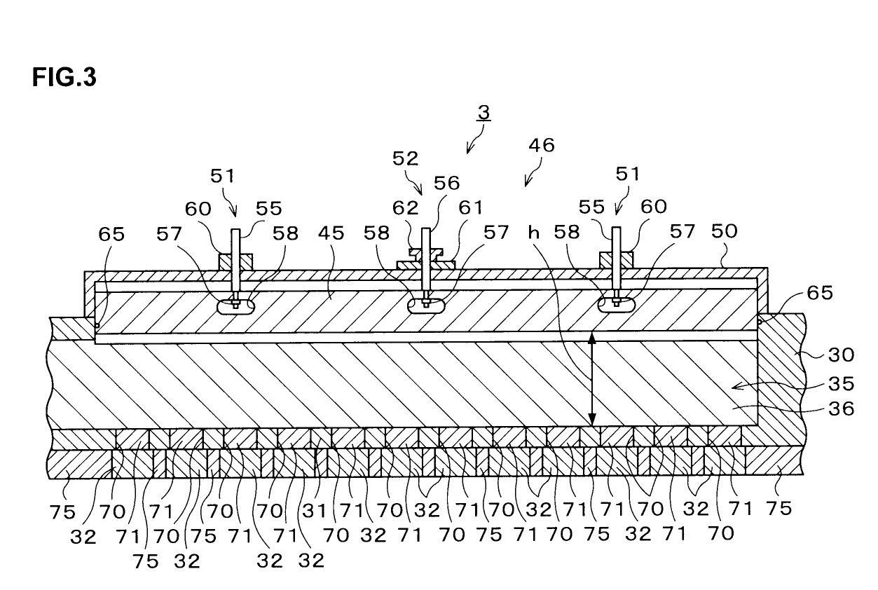

Embodiments of the present invention will be described based on a plasma processing apparatus 1 which performs CVD (chemical vapor deposition) processing as an example of a plasma processing. In the specification and drawings, components having substantially the same function and configuration are shown with the same reference number and detailed description thereof is not repeated. FIG. 1 is a vertical sectional view showing a schematic configuration of the plasma processing apparatus 1 according to an embodiment of the present invention. FIG. 2 is a bottom view of a lid 3 of the plasma processing apparatus 1. FIG. 3 is a partially enlarged vertical sectional view of the lid 3.

The plasma processing apparatus 1 includes a process vessel 2, which is a bottomed cubic shape with an open top, and the lid 3 for covering the top of the process vessel 2. A processing chamber 4, which is an enclosed space, is defined in the process vessel 2 by covering the top of the process vessel 2 with the lid 3. The process vessel 2 and lid 3 are made of aluminum, for example, and made to be electrically grounded.

Inside the processing chamber 4, a susceptor 10 as a mounting table for mounting, for example, a glass substrate G as a substrate (hereinafter, referred to as “substrate”) is provided. The susceptor 10 is made of, for example, aluminum nitride. Inside the susceptor 10, there are a power feeding part 11 for electrostatically attracting the substrate G and applying a predetermined bias voltage to the inside of the processing chamber 4, and a heater 12 for heating the substrate G to a predetermined temperature. A high-frequency power supply 13, which is provided outside the processing chamber 4 and has a capacitor for applying bias voltage and the like, is connected to the power feeding part 11 via a matching device 14 and a high-voltage DC power supply 15 is also connected to the power feeding part 11 via a coil 16 for electrostatic-attracting. An AC power supply 17, which is also provided outside the processing chamber 4, is connected to the heater 12.

The susceptor 10 is supported, via a barrel unit 21, on a lift plate 20 provided outside and under the processing chamber 4 and lifted and lowered together with the lift plate 20 so that the height level of the susceptor 10 in the processing chamber 4 is adjusted. Here, since a bellows 22 is attached between the bottom face of the process vessel 2 and the lift plate 20, the airtightness of the processing chamber 4 is maintained.

At the bottom portion of the process vessel 2, an exhaust port 23 used when atmosphere in the processing chamber 4 is discharged by an exhaust device (not shown) such as a vacuum pump provided outside the processing chamber 4. Further, inside the processing chamber 4, a current plate 24 is provided around the susceptor 10 to control gas flows in the processing chamber 4 to be a desired condition.

The lid 3 has a configuration in which a slot antenna 31 is integrally formed on a lower surface of a lid main body 30, and further, plural tile-like dielectrics 32 are attached on a lower surface of the slot antenna 31. The lid main body 30 and slot antenna 31 are integrally formed using a conductive material such aluminum and electrically grounded. As shown in FIG. 1, when the top of the process vessel 2 is covered by the lid 3, the airtightness of the processing chamber 4 is maintained by an O-ring 33 disposed between a peripheral portion of a lower surface of the lid main body 30 and the top of the process vessel 2 and O-rings (not shown) respectively disposed around later described slots 70.

Inside the lid main body 30, plural rectangular waveguides 35 having a rectangular cross section are horizontally provided. According to the present embodiment, six linearly-extended rectangular waveguides 35 are provided and the respective rectangular waveguides 35 are arranged in parallel so as to be parallel to one another. The respective rectangular waveguides 35 are arranged in a manner that the long side direction of the (rectangular) cross section is referred to as face H and is vertically provided and the short side direction is referred to as face E and is horizontally provided. The arrangement of the long side direction and short side direction is determined according to modes. Further, inside the respective rectangular waveguides 35 is filled with a dielectric member 36 such as fluorocarbon resin (for example, Teflon (registered trademark)), Al2O3, and quartz.

Outside the processing chamber 4, in the present embodiment, there are three microwave feeders 40 as shown in FIG. 2. The microwave feeders 40 respectively supply microwaves of, for example, 2.45 GHz to two the rectangular waveguides 35 provided in the lid main body 30. A Y branch pipe 41 is connected respectively between each of the microwave feeder 40 and the couple of the rectangular waveguides 35 to branch and introduce the microwaves into the couple of rectangular waveguide 35.

As shown in FIG. 1, upper portions of the respective rectangular waveguides 35 formed inside the lid main body 30 are opened on an upper surface of the lid main body 30. A top face 45 is liftably and lowerably inserted into each of the rectangular waveguides 35 from the above of the respective rectangular waveguides 35, which is opened as above. On the other hand, lower faces of the respective rectangular waveguides 35, which are formed in the lid main body 30 constitute the slot antenna 31, which is integrally formed with the lower surface of the lid main body 30. Above the lid main body 30, lift mechanisms 46 for lifting and lowering the top faces 45 of the rectangular waveguides 35 are provided with respect to the lower face of the rectangular waveguide 35 (upper surface of the slot antenna 31) as maintaining the top faces 45 horizontal.

As shown in FIG. 3, the top faces 45 of the rectangular waveguides 35 are disposed in a cover member 50, which is attached so as to cover the upper surface of the lid main body 30. Inside the cover member 50, a space is formed to have a height sufficient for lifting and lowering the top faces 45 of the rectangular waveguides 35. On an upper surface of the cover member 50, there are a pair of guide parts 51 and a lift part 52 disposed between the guide parts 51 and the lift mechanism 46 for lifting and lowering the top faces 45 of the rectangular waveguides 35 is composed of the guide parts 51 and lift part 52.

The top faces 45 of the rectangular waveguides 35 are suspended by the upper surface of the cover member 50 via guide rods 55 provided to the respective guide parts 51 and a lift rod 56 provided to the lift part 52. At respective lower ends of the guide rods 55 and lift rod 56, a nut 57 as a stopper is attached. The nut 57 is engaged with a hole 58 formed inside the top face 45 of the rectangular waveguide 35 to support the top face 45 of the rectangular waveguide 35 not to fall in the cover member 50.

The upper ends of the guide rods 55 and lift rod 56 are projected upward through the cover member 50. The guide rod 55 provided to the guide part 51 passes through a guide 60 fixed on the upper surface of the cover member 50 and is configured to vertically and slidably move in the guide 60. On the other hand, the lift rod 56 provided to the lift part 52 passes through a plate 61 supported on the upper surface of the cover member 50 and a rotation handle 62 rotatably disposed on the plate 61. On the outer peripheral surface of the lift rod 56, thread grooves are formed and the thread grooves are configured to be engaged with a threaded hole formed in the center of the rotation handle 62.

According to the lift mechanism 46, when the rotation handle 62 is operated and rotated, engagement position of the lift rod 56 with respect to the rotation handle 62 is changed and, accordingly, the top face 45 of the rectangular waveguide 35 is lifted and lowered in the cover member 50. When lifting and lowering the top face 45, since the guide rods 55 provided in the guide parts 51 vertically slide in the guides 60, the top face 45 of the rectangular waveguide 35 is always kept horizontal and the top face 45 of the rectangular waveguide 35 is always kept parallel to the lower surface (the upper surface of the slot antenna 31).

Since the rectangular waveguide 35 is filled with the dielectric member 36 as described above, the top face 45 of the rectangular waveguide 35 can be lowered to a position contacting with the upper surface of the dielectric member 36. When the top face 45 of the rectangular waveguide 35 is lifted and lowered in the cover member 50 with a lower limit of the position for contacting the upper surface of the dielectric member 36 in this way by operating the rotation handle 62 to rotate, the height level h of the top face 45 of the rectangular waveguide 35 with respect to the lower surface of the rectangular waveguide 35 (the upper surface of the slot antenna 31) can be arbitrarily changed. Here the height of the cover member 50 is determined in order to lift the top face 45 of the rectangular waveguide 35 to a sufficiently high level to lift or lowered the top face 45 according to a condition of plasma processing performed in the processing chamber 4 as described below.

The top face 45 of the rectangular waveguide 35 is made of a conductive material such as aluminum and a shield spiral 65 for providing an electrical conduct to the lid main body 30 is attached on the circumferential surface portion of the top face 45. The surface of the shield spiral 65 is coated by, for example, gold in order to reduce electrical resistance. Inner walls of the rectangular waveguide 35 are entirely composed of a conductive member and are electrically conductive with each other so that current smoothly flows along the entire inner walls of the rectangular waveguide 35 without being discharged.

On the lower surface of the respective rectangular waveguides 35 which constitute the slot antenna 31, plural slots 70 as through holes are arranged along a long side of the respective rectangular waveguides 35 at even intervals. In the present embodiment, thirteen slots 70 (equivalent to G5) are arranged in series on the respective rectangular waveguides 35, as the entire slot antenna 31, and seventy-eight slots 70 (13×6 rows) are uniformly on the lower surface of the lid main body 30 (the slot antenna 31). The space between the slots 70 is set so that the distance between the center axes of adjacent slots 70 is, for example, λg′/2 (the λg′ is a guide wave length of the initially set microwave when 2.45 GHz) in a longitudinal direction of the respective rectangular waveguides 35.

The respective slots 70, which are arranged entire area of the slot antenna 31 in an evenly spaced manner, are filled with a dielectric member 71 such as fluorocarbon resin, Al2O3 and quartz. Further, under the slots 70, the plural dielectrics 32 attached on the lower surface of the slot antenna 31 are disposed, as described above. The respective dielectrics 32 are formed in a rectangular plate-like shape and made of a dielectric material such as quartz glass, AlN, Al2O3, sapphire, SiN and ceramics.

As shown in FIG. 2, each of the dielectrics 32 is provided so as to cross over the two rectangular waveguides 35, which are connected to the single microwave feeder 40 via the Y branch pipe. As described above, inside the lid main body 30, six rectangular waveguides 35 in total are arranged parallel to each other and the dielectrics 32 are arranged in three rows corresponding to the three couples of the rectangular waveguides 35.

As described above, on the lower surface of each of the rectangular waveguide 35 (slot antenna 31), twelve slots 70 are aligned in series and each of the dielectric 32 is provided so as to cross over the slots 70 of the adjacent two rectangular waveguides 35 (the two rectangular waveguides 35 connected to the same microwave feeder 40 via the Y branch pipe 41). With this structure, on the lower surface of the slot antenna 31, thirty-nine (13×3 rows) dielectrics 32 are provided in total. On the lower surface of the slot antenna 31, there is a beam 75, which is formed in a reticular pattern for supporting the thirty-nine dielectrics 32 arranged in 13×3 rows.

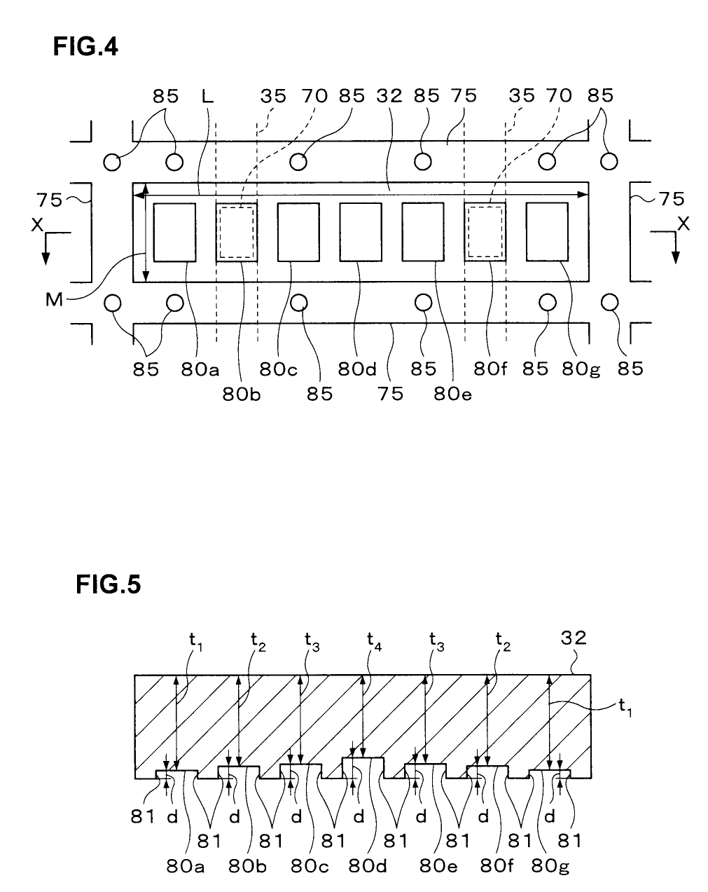

FIG. 4 is an enlarged view of the dielectric 32 as seen from bottom of the lid 3. FIG. 5 is a longitudinal sectional view of the dielectric 32 taken along the line X-X in FIG. 4. The beam 75 is provided so as to surround the circumference of the respective dielectrics 32 and supports the respective dielectrics 32 as closely attaching it to the slot antenna 31. The beam 75 is made of a conductive material such as aluminum and configured to be electrically grounded with the slot antenna 31 and lid main body 30. Since the beam 75 surrounds the circumference of the respective dielectrics 32, most part of the lower surfaces of the respective dielectrics 32 is exposed in the processing chamber 4.

The contact between the respective dielectrics 32 and the respective slots 70 is configured to be sealed using a seal member such as an O-ring (not shown). Microwaves are introduced, for example, in an atmospheric pressure, into the respective rectangular waveguides 35 formed in the lid main body 30; however, since the contact between the respective dielectrics 32 and the respective slots 70 are sealed as above, the airtightness of the processing chamber 4 can be maintained.

The respective dielectrics 32 has a length L in a longitudinal direction longer than a wavelength λg of microwave propagating in the dielectric and a length M in a width direction shorter than the wavelength λg of microwave propagating in the dielectric. When the microwave feeder 40 generates microwaves in, for example, 2.45 GHz, the wavelength λg of the microwave propagating in the dielectric is about 60 mm. The length L of the respective dielectrics 32 in the longitudinal direction is thus set longer than 60 mm, for example, 188 mm. Further, the length M of the respective dielectrics 32 in the width length is set shorter than 60 mm, for example, 40 mm.

On the lower surface of the respective dielectrics 32, concavities and convexities are formed. In other words, according to the present embodiment, seven concave portions 80a, 80b, 80c, 80d, 80e, 80f, 80g are provided in series on the rectangular lower surface of the respective dielectrics 32, along the longitudinal direction. These concave portions 80a to 80g are formed in a substantially the same rectangular shape as seen from the above. Further, inner surfaces of the respective concave portions 80a to 80g are formed as substantially vertical wall surfaces 81.

As described above, the respective dielectrics 32 are attached so as to cross over the slots 70 of the two adjacent rectangular waveguides 35 (the two rectangular waveguides 35 connected to the same microwave feeder 40 via the Y branch pipe 41). Here, among the concave portions 80a to 80g, the center concave portion 80d is placed at a substantially midpoint between the one slot 70 of the rectangular waveguide 35 and the other slot 70 of the rectangular waveguide 35, the concave portion 80a to 80c are placed in the side of the one slot 70 of the rectangular waveguide 35 as seen from the concave portion 80d, and the concave portions 80e to 80g are placed in the side of the other slot 70 of the rectangular waveguide 35 as seen from the concave portion 80d. In the side of the one slot 70 of the rectangular waveguide 35, among the concave portion 80a to 80c, the center concave portion 80b is placed just under the one slot 70 of the rectangular waveguide 35 and the concave portions 80a, 80c are placed in both sides thereof. Similarly, in the side of the other slot 70 of the rectangular waveguide 35, among the concave portion 80e to 80g, the center concave portion 80f is placed just under the other slot 70 of the rectangular waveguide 35 and the concave portions 80e, 80g are placed in the both sides thereof.

The depths d of the respective concave portions 80a to 80g are not the same and some of the concave portions 80a to 80g or all of them can be formed to have different depths d. In other words, the depths d of the respective concave portions 80a to 80g are basically formed to be deeper as being placed farther from the slots 70. Describing concretely based on the embodiment shown in FIG. 5, the concave portions 80b, 80f, which are placed closest to the slots 70, have shallowest depth d and the concave portion 80d, which is placed farthest from the slots 70, has a deepest depth d. The concave portions 80a, 80c and the concave portions 80e, 80g, which are placed in both sides of the concave portion 80b, 80f just under the slots 70, have medium depths d, compared to the depths d of the concave portions 80b, 80f just under the slots 70 and the depth d of the concave portion 80d placed farthest from the slots 70.

Here, regarding the concave portions 80a, 80g placed at longitudinal ends of the dielectric 32 and the concave portions 80c, 80e placed interior to the two slots 70, although the distance between these concave portions 80a, 80g and the slots 70 and the distance between the concave portions 80c, 80e and the slots 70 are the same, the strength of generated plasma is increased in the concave portions 80a, 80g placed in the longitudinal ends of the dielectric 32 due to standing waves generated at the longitudinal ends of the dielectric 32 as described below. With this reason, the depths d of the concave portions 80a, 80g placed at the ends are made shallower than the depths d of the concave portions 80c, 80e placed interior to the slots 70. Thus, according to the present embodiment, the relation of the depths d of the respective concave portions 80a to 80g is as follows: the depths d of the concave portions 80b, 80f placed closest to the slots 70<the depths d of the concave portions 80a, 80g placed at the longitudinal ends of the dielectric 32<the depths d of the concave portions 80c, 80e placed interior to the slots 70<the depth d of the concave portion 80 placed farthest from the slots 70.

A thickness t1 of the dielectric 32 at the concave portion 80a and concave portion 80g, a thickness t2 of the dielectric 32 at the concave portion 80b and concave portion 80f and a thickness t3 of the dielectric 32 at the concave portion 80c and concave portion 80e are respectively set not to practically disturb propagations of microwaves at the concave portions 80a to 80c and propagations of microwaves at the concave portions 80e to 80g when propagating microwave in the dielectric 32 as described below. On the other hand, a thickness t4 of the dielectric 32 at the concave portion 80d is set so as to generate a so-called cutoff at the concave portion 80d and not to practically propagate microwaves at the concave portion 80d when propagating microwave in the dielectric 32 as described below. With this structure, the microwave propagation at the concave portions 80a to 80c placed in the side of one slot 70 of the rectangular waveguide 35 and the microwave propagation at the concave portions 80e to 80g in the side of the other slot 70 of the rectangular waveguide 35 are cut off at the concave portion 80d not to interfere with each other. This prevents interference between the microwaves from the one slot of the rectangular waveguide 35 and the microwaves from the other slot of the rectangular waveguide 35.

On the lower surface of the beam 75 for supporting the respective dielectrics 32, gas ejecting ports 85 for supplying processing gas to the processing chamber 4 are respectively provided around the dielectric 32. Since the gas ejecting ports 85 are formed at plural positions so as to surround the respective dielectrics 32, the gas ejecting ports 85 are uniformly distributed on the entire upper surface of the processing chamber 4.

As shown in FIG. 1, inside the lid main body 30, gas pipes 90 for supplying processing gas and cooling water pipes 91 for supplying cooling water are provided. The gas pipes 90 respectively communicate with the gas ejecting ports 85 provided on the lower surface of the beam 75.

The gas pipes 90 are connected to a processing gas supply source 95 disposed outside the processing chamber 4. In the present embodiment, an argon gas supply source 100, a silane gas (as a film-forming gas) supply source 101 and a hydrogen gas supply source 102 are prepared as the processing gas supply source 95 and are respectively connected to the gas pipes 90 via valves 100a, 101a, 102a, mass flow controllers 100b, 101b, 102b, and valves 100c, 101c. With this structure, the processing gas supplied from the processing gas supply source 95 to the gas pipe 90 is ejected into the processing chamber 4 via the gas ejecting ports 85.

The cooling water pipe 91 is connected to a cooling water supply source 105 disposed outside the processing chamber 4. Since cooling water is cyclically supplied from the cooling water supply source 105 to the cooling water pipes 91, the lid main body 30 is kept in a predetermined temperature.

A case of forming, for example, an amorphous silicon film in the plasma processing apparatus 1 according to the embodiment of the present invention having the above described configuration will be described. When treating, the substrate G is mounted on the susceptor 10 in the processing chamber 4 and, while a predetermined processing gas such as a mixed gas of argon gas, silane gas and hydrogen gas is supplied from the processing gas supply source 95 to the processing chamber 4 via the gas pipes 90 and gas ejecting ports 85, the gas is discharged from the exhaust port 23 to set the processing chamber 4 to a predetermined pressure. In this case, the processing gas is ejected from the gas ejecting ports 85 provided on the entire lower surface of the lid main body 30 so that the processing gas can be evenly supplied to all over the front surface of the substrate G mounted on the susceptor 10.

While supplying the processing gas into the processing chamber 4, the heater 12 heats the substrate G to a predetermined temperature. Further, the microwave in, for example, 2.45 GHz, generated in the microwave feeder 40 shown in FIG. 2 is introduced into the respective rectangular waveguides 35 via the Y branch pipes 41 and propagated in the respective dielectrics 32 via the respective slots 70. When the microwave introduced into the rectangular waveguides 35 is propagated in the respective dielectrics 32 via the slots 70 as above, the microwave cannot be introduced from the rectangular waveguides 35 through the slots 70 if the size of the slots 70 is not enough. However, in this embodiment, the respective slots 70 are filled with a dielectric member 71 having a high dielectric constant such as fluorocarbon resin, Al2O3, quartz. Thus, even if the slot 70 is not large enough, the slot 70 is appeared to have a function, which is the same as the slot 70 having a sufficiently large size, to introducing the microwave using the dielectric member 71. With this structure, the microwave introduced in the rectangular waveguide 35 can be surely propagated into the respective dielectrics 32 via the slots 70.

In this case, when the longitudinal length of the rectangular waveguide 35 is referred to as “a,” the wavelength (guide wavelength) of the microwaves propagating in the rectangular waveguide 35 is referred to as “k” and the dielectric constant of the dielectric member 71 provided in the slots 70 is referred to as “∈,” then, a dielectric can be selected to provide a relation of λg/√∈≦2a. For example, regarding fluorocarbon resin, Al2O3 and quartz, when the dielectric member 71 composed of Al2O3 which has the highest dielectric constant is provided in the slots 70, the most amount of microwaves can be propagated to the dielectric 32 via the slots 70. Further, regarding the slots 70 of the rectangular waveguide 35 having the same longitudinal length “a,” when different dielectric member 71 having different dielectric constants is provided in the slots 70, the amount of the microwaves propagated to the dielectric 32 via the slots 70 can be controlled.

Thus, using the energy of the microwave propagated in the respective dielectrics 32, an electromagnetic field is formed on the respective dielectrics 32 in the processing chamber 4 and, using the electric field energy, the processing gas in the process vessel 2 is made into plasma. As a result, an amorphous silicon film is formed on the front surface of the substrate G. In this case, since the concave portions 80a to 80g are formed on the lower surface of the respective dielectrics 32, the microwaves are propagated to the inner surface (wall surfaces 81) of the concave portions 80a to 80g by the energy of the microwaves propagated in the dielectric 32. Then, a substantially vertical electric field is formed to the wall surface 81 by the energy of the microwaves propagated in the concave portions 80a to 80g and accordingly plasma can be generated in the vicinity of the electric field. The area where the plasma is generated can also be stable.

Further, since the depths d of the concave portions 80a to 80g formed on the lower surface of the respective dielectrics 32 are made different from each other, plasma can be generated evenly on the entire of the lower surface of the respective dielectrics 32. In other words, when the microwaves propagated in the dielectric 32 from the slots 70 enters into the processing chamber 4, the strength of the electric field formed on the front surface of the dielectric 32 by the energy of the microwaves is reduced as getting farther from the slots 70. However, according to the embodiment shown in FIG. 5, the depth d of the respective concave portions 80a to 80g are basically formed deeper as being placed farther form the slots 70. Thus, since the area of the inner surface (wall surface 81) of the concave portion becomes larger as the position of the concave portion is farther from the slots 70, even when the strength of the electric field is reduced as getting farther from the slots 70, the area for emitting the electric field is made larger corresponding to the reduced electric field strength and the electric field is formed almost all area of the larger inner surface (wall surface 81). As a result, plasma can be efficiently generated. As described above, the depths of the concave portions 80a, 80c, 80d, 80e, 80g placed farther from the slots 70 is made deeper than the depths of the concave portions 80b, 80f placed closer the slots 70 so that the reduction of the electric field strength can be compensated and plasma can be generated evenly on the entire lower surface of the dielectric.

On the other hand, the microwave propagated into the dielectric 32 from the slots 70 is propagated to the longitudinal ends of the dielectric 32, reflected by the beam 75 placed as surrounding the dielectric 32, and then propagated to the concave portions 80a, 80g at the both ends as standing waves. Thus in the concave portions 80a, 80g at the both ends, the strength of plasma generated by this standing wave is increased; however, since the depths d of the concave portions 80a, 80g at the both ends are made shallower in view of the influence of the standing wave, substantially even plasma strength can be obtained n even in the both ends of the dielectric 32. Further, it can be prevented that the generating strength of plasma is partially increased at the concave portions 80a, 80g at the both ends due to reflected waves reflected by the beam 75 supporting the dielectric 32.

As described above, the microwaves are propagated from the two slots 70 into the respective dielectrics 32. Here, the interference between the microwaves propagated from the two slots 70 can be prevented at the concave portion 80d provided in the center of the respective dielectrics 32. In other words, as has been described with reference to FIGS. 4 and 5, the microwave from the one slot 70 of the rectangular waveguide 35 is propagated in the dielectric 32 at the concave portions 80a to 80c and forms an electric field on the inner surfaces (wall surface 81) of the concave portions 80a to 80c to generate plasma. In this case, the microwaves from the one slot 70 of the rectangular waveguide 35 are propagated in the dielectric 32 at the concave portions 80a to 80c; however, the microwaves are cut off at the concave portion 80d and are not propagated to the positions of the concave portions 80e to 80g. Similarly, the microwaves from the other slot 70 of the rectangular waveguide 35 are propagated in the dielectric 32 at the concave portions 80e to 80g and forms an electric field on the inner surfaces (wall surface 81) of the concave portions 80e to 80g to generate plasma. In this case, the microwaves from the other slot 70 of the rectangular waveguide 35 are propagated in the dielectric 32 at the concave portions 80e to 80g; however, the microwaves are cut off at the concave portion 80d and are not propagated to the positions of the concave portions 80a to 80c. The microwaves from the respective slots 70 are efficiently used for generating plasma on the front surface of the dielectric 32 (the inner surfaces of the concave portions 80a to 80 and concave portions 80e to 80g). Further, the microwaves propagated from the respective slots 70 to the dielectric 32 hardly turn back into the rectangular waveguide 35 from the slots 70 and a generation of reflected waves is suppressed.

Here, in the processing chamber 4, using, for example, a low electron temperature from 0.7 eV to 2.0 eV and high-density plasma from 1011 to 1013 cm-3, an even film forming having less damage to the substrate G is performed. An appropriate condition for forming an amorphous silicon film is that, for example, the pressure in the processing chamber 4 is from 5 to 100 Pa, preferably from 10 to 60 Pa, and the temperature of the substrate G is from 200 to 450° C., preferably from 250 to 380° C. Further, the size of the processing chamber 4 is preferably larger than G3, for example, G4.5 (the size of the substrate G: 730 mm×920 mm, the inner size of the processing chamber 4: 1000 mm×1190 mm), G5 (the size of the substrate G: 1100 mm×1300 mm, the inner size of the processing chamber 4: 1470 mm×1590 mm), and the output power of the microwave feeder is from 1 to 4 W/cm2, preferably 3 W/cm2. When the output power of the microwave feeder is greater than 1 W/cm2, the plasma is ignited and the generation of plasma becomes relatively stable. When the output power of the microwave feeder is lower than 1 W/cm2, sometimes plasma is not ignited or the generation of plasma becomes very unstable so that the process becomes too unstable and uneven for practical use.

Here, the condition for plasma processing performed in the processing chamber 4 (for example, gas type, pressure, output power of the microwave feeder, etc.) is arbitrarily determined according to the type of processing; however, when the impedance in the processing chamber 4 with respect to the plasma generation is changed by changing the condition of the plasma processing, the wavelength (guide wavelength λg) of the microwave propagated in the respective rectangular waveguides 35 is tend to be changed accordingly. On the other hand, as described above, since the slots 70 are provided with a predetermined intervals (λg′/2) to the respective rectangular waveguides 35, the impedance is changed according to the condition for plasma processing, and when the guide wavelength λg is changed accordingly, the intervals (λg′/2) between the slots 70 and the practical half length of the guide wavelength λg does not match. As a result, the microwaves cannot efficiently propagated in the respective dielectrics 32 on the upper surface of the processing chamber 4 from the respective slots 70, which are arranged along the longitudinal direction of the respective rectangular waveguides 35.

According to the embodiment of the present invention, when the impedance is changed according to the condition for the plasma processing executed in the processing chamber 4 such as kind of gas, pressure, output power of the microwave feeder and the like and the guide wavelength λg is changed accordingly, the changed wavelength λg can be adjusted by lifting and lowering the top faces 45 of the rectangular waveguide 35 with respect to the lower surface (upper surface of the slot antenna 31). In other words, when the actual guide wavelength λg becomes shorter according to the condition of the plasma processing performed in the processing chamber 4, the top face 45 of the rectangular waveguide 35 is lowered in the cover member 50 by operating the rotation handle 62 of the lift mechanism 46 to rotate. When the height level h of the top face 45 with respect to the lower surface of the respective rectangular waveguides 35 is lowered in this way, the guide wavelength λg is made to be longer and the gap between the interval between the slots (λg′/2) and the locations of the top portions and bottom portions of the actual guide wavelength λg is prevented so that the top portions and bottom portions of the guide wavelength λg can be matched with the locations of the slots 70. In contrast, when the actual guide wavelength λg becomes longer according to the condition of the plasma processing performed in the processing chamber 4, the top face 45 of the rectangular waveguide 35 is lifted in the cover member 50 by operating the rotation handle 62 of the lift mechanism 46 to rotate. When the height level h of the top face 45 with respect to the lower face of the respective rectangular waveguides 35 is lifted, the guide wavelength λg is made to be longer and the gap between the slots interval between the slots (λg′/2) and the actual guide wavelength λg is prevented and the top portions and bottom portions of the guide wavelength λg can be matched with the locations of the slots 70.

As described above, the height level h of the top face 45 with respect to the lower surface of the respective rectangular waveguides 35 can be arbitrarily changed by lifting and lowering the top face 45 of the rectangular waveguide 35 with respect to the lower surface (upper surface of the slot antenna 31) so that the guide wavelength λg of microwaves can be changed and the interval of the top portions and bottom portions of the actual guide wavelength λg can be matched with the portions of the slots 70. As a result, the microwaves can efficiently be propagated from the respective slots 70 formed on the lower surface of the rectangular waveguide 35 into the respective dielectrics 32 on the upper surface of the processing chamber 4, an even electromagnetic field can be formed all over the upper face of the substrate G and an even plasma processing can be performed on the entire front surface of the substrate G. Since it is not required to change the intervals between the slots 70 according to the plasma processing condition by changing the guide wavelength λg of the microwave, its facility cost can be reduced, and further, different types of plasma processing can sequentially be performed in the processing chamber 4.

In addition, according to the plasma processing apparatus 1 of the present embodiment, since plural tile-like dielectrics 32 are attached on the upper surface of the processing chamber 4, the respective dielectrics 32 can be downsized and lightened. Thus, the manufacturing the plasma processing apparatus 1 can be made easier and less expensive and readiness to the large sized substrates G can be improved. Further, since the slots 70 are provided to the respective dielectrics 32, each area of the respective dielectrics 32 is remarkably small, and the concave portions 80a to 80g are formed on the lower surface of the dielectrics 32, microwaves can evenly be propagated in the respective dielectrics 32 and plasma can efficiently be generated on the entire lower surface of the respective dielectrics 32. An even plasma processing can be performed in the entire processing chamber 4.

As has been described in the present embodiment, the dielectric 32 is formed in a rectangular shape. The width of the dielectric 32 is made, for example, 40 mm that is narrower than the wavelength λg, which is about 60 mm, of the microwaves propagating in the dielectric and the longitudinal length of the dielectric 32 is made, for example, 188 mm that is longer than the wavelength λg, which is about 60 mm, of the microwaves propagating in the dielectric so that a structure in which a surface wave propagates in the dielectric 32 in a longitudinal direction can be obtained. In this case, at the longitudinal ends of the dielectric 32, standing waves are generated due to interference between reflected wave caused by a reflection of the surface wave and traveling waves. At both ends of the dielectric 32 in a width direction, since the width of the dielectric 32 is made, for example, 40 mm, a generation of standing waves can be prevented. Further, in order to suppress an influence of standing wave generated at the both longitudinal ends of the dielectric 32 as much as possible, the depths of the concave portions 80a, 80g disposed at the ends of the lower surface of the dielectric 32 is preferably the same level of the depths of the concave portions 80b, 80f placed just under the slots 70. Further, the influence of the surface waves at the longitudinal ends of the dielectric 32 can be reduced by adjusting the intervals between the concave portions 80a to 80g aligned on the lower surface of the dielectric 32 and, as a result, the generation of the standing waves at the longitudinal ends of the dielectric 32 can be minimized. Thus, a wide process window can be provided and a stable plasma processing is achieved. Further, since the beam 75 (supporting member) for supporting the dielectric 32 can be made thin, the most part of the lower surface of the respective dielectrics 32 is exposed in the processing chamber 4. Thus, the beam 75 hardly disturbs when an electromagnetic field is formed in the processing chamber 4 and an even electromagnetic field can be formed entirely above substrate G so that even plasma can be generated in the processing chamber 4.

As shown in the plasma processing apparatus 1 of the present embodiment, the gas ejecting ports 85 for supplying processing gas can be provided to the beam 75, which supports the dielectric 32. Further, as has been described in the embodiment, when the beam 75 is made of metal such as aluminum, it is easy to form the gas ejecting ports 85 and the like.

In the foregoing, the preferred embodiment of the present invention has been described, but the present invention is not limited to such examples. For example, the lift mechanism 46 for lifting or lowering the top face 45 of the rectangular waveguide 35 is not have to be composed of the guide parts 51 and lift part 52 as shown in the figures and can lift or lower the top face 45 of the rectangular waveguide 35 using a cylinder or other drive mechanism. According to the embodiment shown in the figures, an example for lifting and lowering the top face 45 of the rectangular waveguide 35 has been described, but the height level h of the top face 45 with respect to the lower surface of the rectangular waveguide 35 (slot antenna 31) can be changed by lowering the lower surface of the rectangular waveguide 35 (slot antenna 31).

Further, the example, in which the dielectric member 36 such as fluorocarbon resin, Al2O3 and quartz are disposed inside the respective rectangular waveguides 35, has been described; however, the inside of the respective rectangular waveguides 35 can be made hollow. When the dielectric member 36 is disposed inside the rectangular waveguide 35, the guide wavelength λ can be made shorter, compared to a case that the inside of the rectangular waveguide 35 is made hollow. With such a structure, the intervals between the slots 70 aligned in a longitudinal direction of the rectangular waveguide 35 can be made shorter so that the number of the slots 70 can be increased accordingly. Thus, when the dielectric 32 can be further downsized and the number of dielectrics 32 can further increased and accordingly, the dielectric 32 can be downsized and lightened and the effects such as an even plasma processing in the entire processing chamber 4 can be further improved.

When the dielectric member 36 is disposed in the rectangular waveguide 35, the upper potion in the rectangular waveguide 35 becomes partially hollow since the top face 45 is lifted or lowered. In such a case, the dielectric constant in the rectangular waveguide 35 becomes a value between the dielectric constant of the dielectric member 36 and the dielectric constant of air in the upper portion of the rectangular waveguide 35. For example, when fluorocarbon resin having a dielectric constant relatively close to that of air is employed as the dielectric member 36 (the dielectric constant of air is about 1 and the dielectric constant of fluorocarbon resin is about 2), the influence corresponding to the size of the hollow formed in the upper portion of the rectangular waveguide 35 can be reduced. On the other hand, for example, when Al2O3 having a dielectric constant considerably different from that of air is employed as the dielectric member 36 (the dielectric constant of Al2O3 is about 9), the influence corresponding to the size of the hollow formed in the upper portion of the rectangular waveguide 35 can be increased.

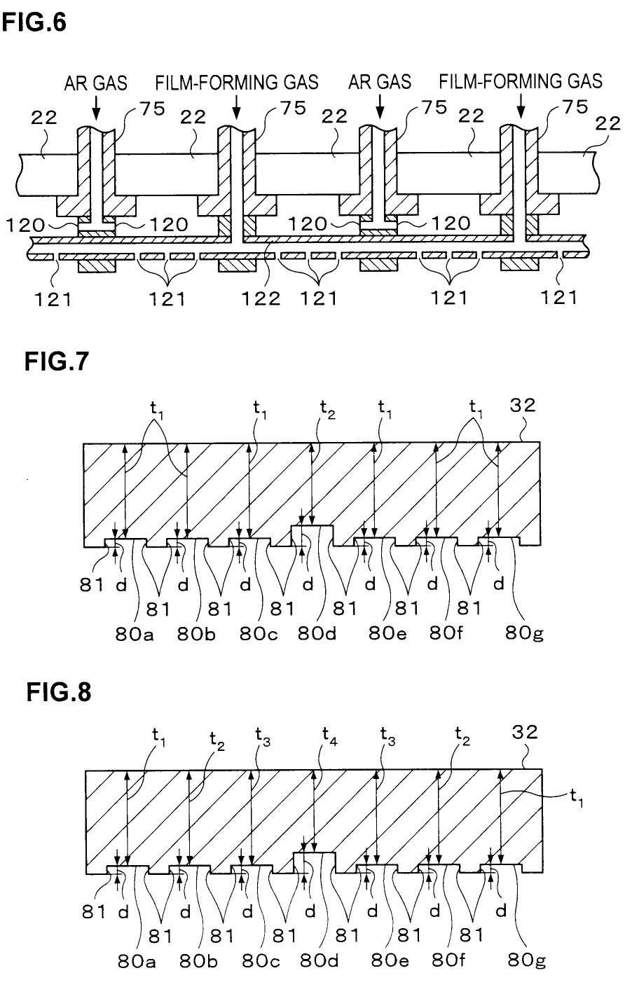

As shown in FIG. 6, one or more first gas ejecting port 120 for supplying Ar gas supplied form, for example, the argon gas supply source 100 as a first processing gas into the processing chamber 4 and one or more second gas ejecting port 121 for supplying film-forming gas supplied from, for example, the silane gas supply source 101 and hydrogen gas supply source 102 as a second processing gas in to the processing chamber 4 can be separately provided around the dielectric 32. In the example shown in the figure, a pipe 122 is attached by a supporting member 123, in a manner of being parallel to the lower surface of the beam 75, with an appropriate distance from the lower surface of the beam 75, which supports the dielectric 32. Then, a side face of the supporting member 123 is opened to form the first gas ejecting port 120 near the lower face of the dielectric 32 and Ar gas supplied from the argon gas supply source 100 is supplied from the first gas ejecting port 120 into the processing chamber 4 through the beam 75 and supporting member 123. Further, a lower face of the pipe 122 is opened to form the second gas ejecting port 121 and film-forming gas supplied from the silane gas supply source 101 and hydrogen gas supply source 102 from the second gas ejecting port 121 into the processing chamber 4 through the beam 75, supporting member 123 and pipe 122.

With such a configuration, since the second gas ejecting port 121 for supplying the film-forming gas is disposed lower than the first gas ejecting port 120 for supplying the Ar gas, the Ar gas is supplied near the lower surface of the dielectric 32 and the film-forming gas is supplied from the position lower than the lower surface of the dielectric 32. Thus in the vicinity of the dielectric 32, the inert Ar gas is made into plasma using a relatively strong electric field to and the activated film-forming gas is made into plasma using a weaker electric field and Ar plasma. This provides operation and effect that the silane gas as the film-forming gas is dissociated into SiH3 radical as a precursor and not into SiH2.

The depths d of the plural concave portions formed on the lower surface of the dielectric 32 can be any depth if the all depths are not the same. For example, the depths d of all the concave portions can be differ or the depths d of some of the concave portions can be different. For example, as shown in FIG. 7, it is possible that, among the seven concave portions 80a to 80g provided on the lower surface of the dielectric 32, the concave portion 80d in the middle is formed deepest and other concave portions 80a to 80c and concave portions 80e to 80g are formed to have the same level of depths d.

According to the embodiment shown in FIG. 7, the thickness t1 of the dielectric 32 at the concave portions 80a to 80c and concave portions 80e to 80g is set not to practically disturb the microwave propagation. On the other hand, the thickness t2 of the dielectric 32 at the concave portion 80d is set not to practically allow the microwave propagation. With this structure, similarly to the above, the microwave propagation at the concave portions 80a to 80c placed in the side of the one slot 70 of rectangular waveguide 35 and the microwave propagation at the concave portions 80e to 80g placed in the side of other slot 70 of the rectangular waveguide 35 are cut off at the concave portion 80d and are not interfered with each other.

According to the embodiment shown in FIG. 5, the relation of the depths d of the respective concave portions 80a to 80g is described as: the depth d of the concave portions 80b, 80f placed closest to the slots 70<the depth d of the concave portions 80a, 80g placed at the longitudinal ends of the dielectric 32<the depth d of the concave portions 80c, 80e placed between the slots 70<the depth d of the concave portion 80d placed farthest from the slots 70. However, in view of the standing waves generated at the longitudinal ends of the dielectric 32, the depths d of the concave portions 80a, 80g placed at the longitudinal ends of the dielectric 32 can be made to be the same level as the depths d of the concave portions 80b, 80f placed just under the slots 70. The relation of the sizes of the depths d of the concave portions 80a, 80g and the depths d of the concave portions 80b, 80f can be determined in view of the attenuance of microwaves propagated in the dielectric 32, influences of standing waves generated at the longitudinal ends of the dielectric 32, and the like.

According to the embodiments shown in FIGS. 5 and 7, it is described that the concave portion 80d placed at the middle of the slots 70 is made deepest on the lower surface of the dielectric 32, which is attached so as to cross over the two slots 70. However, between the two slots 70, the depth of the concave portions 80c, 80e, which is not placed at the middle, can be made deepest. In other words, according to the embodiment shown in FIG. 8, among the three concave portions 80c, 80d, 80e formed between the two slots 70, the depth d of the concave portions 80c, 80e placed adjacent to and between the concave portions 80b, 80f just under the slots 70 are formed deeper than the depth d of the concave portion 80d placed in the middle between the slots 70. According to this embodiment, the relation of the depths d of the respective concave portions 80a to 80g can be described as: the depth d of the concave portions 80b, 80f placed closest to the slots 70<the depths d of the concave portion 80a, 80g placed at the longitudinal ends of the dielectric 32<the depth d of the concave portion 80d placed farthest from the slots 70<the depths d of the concave portions 80c, 80e placed between the slots 70.

According to this structure, the strength of the electric field formed on the surface of the dielectric 32 using the energy of the microwaves when the microwave propagated in the dielectric 32 from the slots 70 is introduced in the processing chamber 4 is lowered as being farther from the slots 70; however, at the concave portion 80d placed in the middle of the slots 70, energy of the microwaves propagated from both of the two slots 70 are superimposed and an electric field is formed. Thus, even when the electric field strength is reduced corresponding to the distance from the slots 70, the energy of the microwave propagated from two slots 70 are added and the reduction of the electric field strength can be compensated. As described above, between the two slots 70, the depth d of the concave portion 80d placed in the middle is made shallower than the depths d of the concave portions 80c, 80e placed interior to the slots 70 so that plasma can be generated substantially even on the entire lower surface of the dielectric 32.

The number of the concave portions provided on the lower surface of the dielectric 32, shape or arrangement of the concave portions can be arbitrarily determined. A single concave portion can be formed on the lower surface of the dielectric 32, or, plural concave portions can be formed on the lower surface of the dielectric 32, as shown in the figures. When a single concave portion is formed on the lower surface of the dielectric 32, preferably, the depth of the concave portion is changed corresponding to the distance from the slots 70 so that the depths of the concave portion becomes deeper as being farther from the slots 70. Further, when plural concave portions are formed on the lower surface of the dielectric 32, the shapes of the respective concave portions can be differ. Or, a concave portion can be formed on the lower surface of the dielectric 32 by providing a convex portion on the lower surface of the dielectric 32. With any of the structures, when a concave portion is provided on the lower surface of the dielectric 32 and a substantially vertical wall surface is formed on the lower surface of the dielectric 32, a substantially vertical electric field is formed on the substantially vertical wall surface using energy of the propagated microwaves. As a result, plasma can be efficiently generated in the vicinity of the wall surfaces and the area where the plasma is generated can also made to be stable.

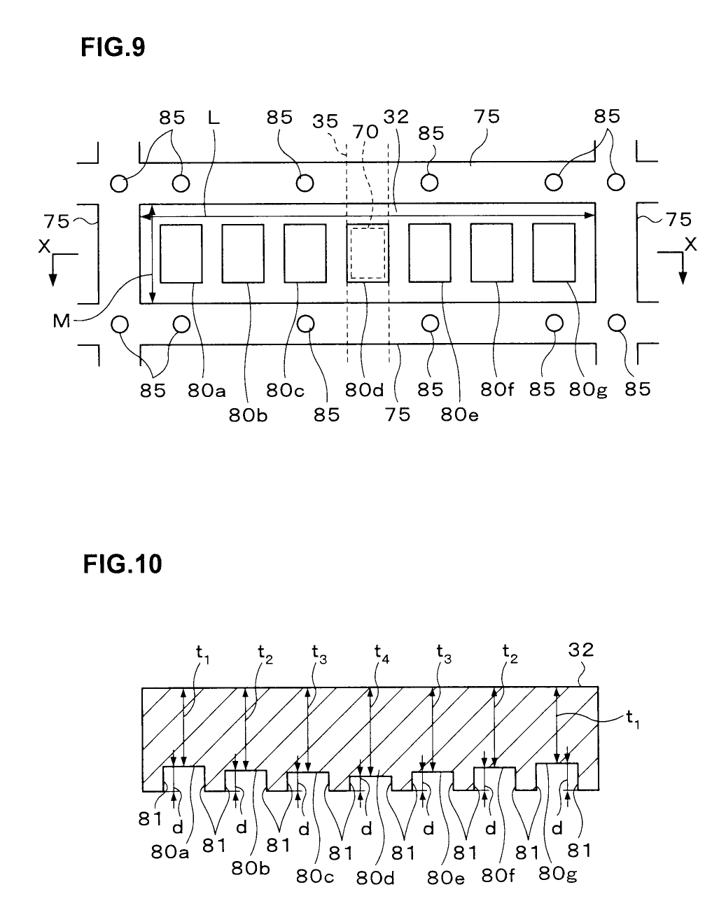

According to the embodiment shown in the figures, the dielectric 32 is attached so as to cross over the two slots 70; however, the same number of the dielectrics and slots are provided and a dielectric 32 can be provided for every slot 70. In this case, also, one or more concave portions are formed on the lower surface of the dielectric and the depths of the concave portions are changed corresponding to the distance from the slot. In this case, also, when a single concave portion is formed on the lower surface of the dielectric, the depth of the concave portion is changed corresponding to the distance from the slot so that the depth of the concave portion becomes deeper as being farther from the slot. Further, when plural concave portions are formed on the lower surface of the dielectric, the depths of the concave portions formed farther from the slots 70 are made deeper than the depths of the concave portions formed closer to the slots 70. As shown in FIGS. 9 and 10, for example, among the concave portions 80a to 80g, the concave portion 80d in the middle is placed just under the slots 70 of the rectangular waveguide 35 and the concave portions 80a to 80c and the concave portions 80e to 80g are placed in both sides thereof. In this case, the depth d of the concave portion 80d placed closest to the slots 70 is made shallowest and the depths d of the concave portions 80a to 80c and the depths d of the concave portions 80e to 80g are made deeper as being farther from the slots 70. Here, the depths d of the concave portions 80a, 80g placed in the longitudinal ends of the dielectric 32 can be shallower than the depths d of the concave portions interior to the concave portions 80a, 80g (for example, concave portions 80b, 80f) in view of the influence of standing waves generated at the both longitudinal ends of the dielectric 32.

The longitudinal direction of the cross-section (rectangular shape) of the respective rectangular waveguides 35 can be a face E that is horizontally disposed and the width direction can be a face H that is vertically disposed. Here, as described the embodiments shown in the figures, when the longitudinal direction of the cross-section (rectangular shape of the rectangular waveguide 35 is referred to as the face H that is vertical and the width direction is referred to as the face E that is horizontal, the intervals between the respective rectangular waveguides 35 can be made wider so that it becomes easier to dispose, for example, the gas pipe 90 and the cooling water pipe 91 and to increase the number of the provided rectangular waveguides 35.

The shapes of the slots 70 formed on the slot antenna 31 can be various shapes such as a slit-like shape. Further, the plural sots 70 can be linearly arranged or so-called a radial line slot antenna can be composed by arranging the slots spirally or concentrically. The shape of the dielectric 32 does not have to be a rectangular shape and can be, for example, a square shape, triangular shape, any polygonal shape, disk-like shape, ellipsoidal shape and the like. Further, the respective dielectrics 32 can be formed in the same shape or different shapes.

According to the above embodiments, a device for forming an amorphous silicon film, which is an example of plasma processing, has been described; however, the present invention can be applied not only to the amorphous silicon film formation but also to an oxide film formation, an oxide film formation, a polysilicon film formation, a silane-ammonia processing, a silane-hydrogen processing, an oxide film processing, a silane-oxide processing, other CVD processing and etching processing.

### EXAMPLES

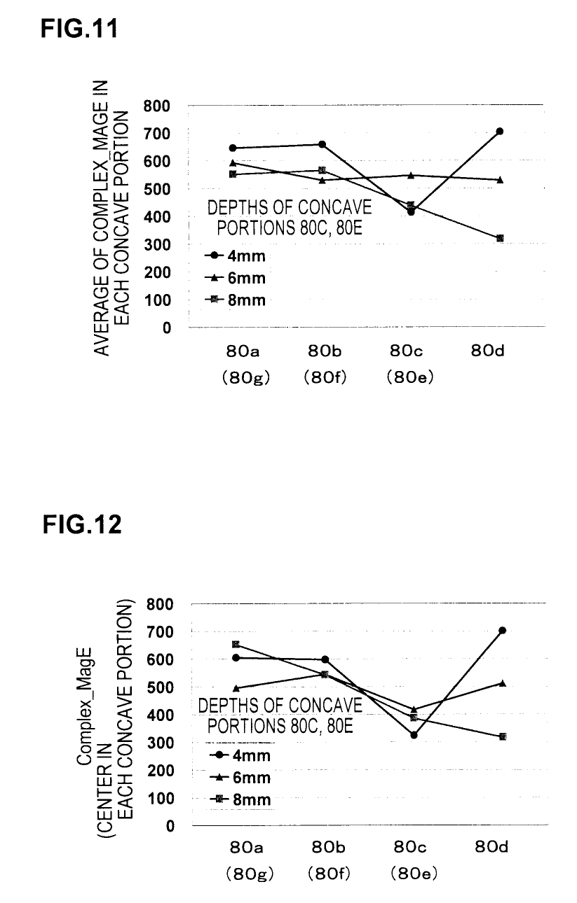

Regarding the structure, as shown in the embodiment of FIG. 8, in which, among the concave portions 80c, 80d, 80e formed between the two slots 70, the depths d of the concave portions 80c, 80e placed adjacent to and interior to the concave portions 80b, 80f just under the slots 70 are made deeper than the depth of the concave portion 80d placed in the middle between the slots 70, dependence properties of electric field strength distribution with respect to the depths of the respective concave portions 80a to 80g are simulated. In this example, the depths d of the concave portions 80a, 80g placed at the longitudinal ends of the dielectric 3 are made 4 mm, the depths d of the concave portions 80b, 80f placed closest to the slots 70s is made 2.5 mm, the depth d of the concave portion 80d placed in the middle between the slots 70 is made 5 mm. Then the depths d of the concave portions 80c, 80e placed interior to the slots 70 are changed to be 4 mm, 6 mm and 8 mm. In order to compare the electric field strengths, average values of the maximum electric field strengths (Complex MagE) in the respective concave portions 80a to 80g per cycle and the maximum electric field strength (Complex MagE) in the center of the respective concave portions 80a to 80g are respectively obtained. Then, FIG. 11 (average of maximum electric field strengths) and FIG. 12 (maximum electric field strengths) are obtained. As a result, as shown in FIGS. 11 and 12, the maximum electric field strengths of the respective concave portions 80a to 80g had the least variation when the depths d of the concave portions 80c, 80e placed interior to the slots 70 were 6 mm and plasma was able to be generated substantially evenly on the entire lower surface of the dielectric 32.

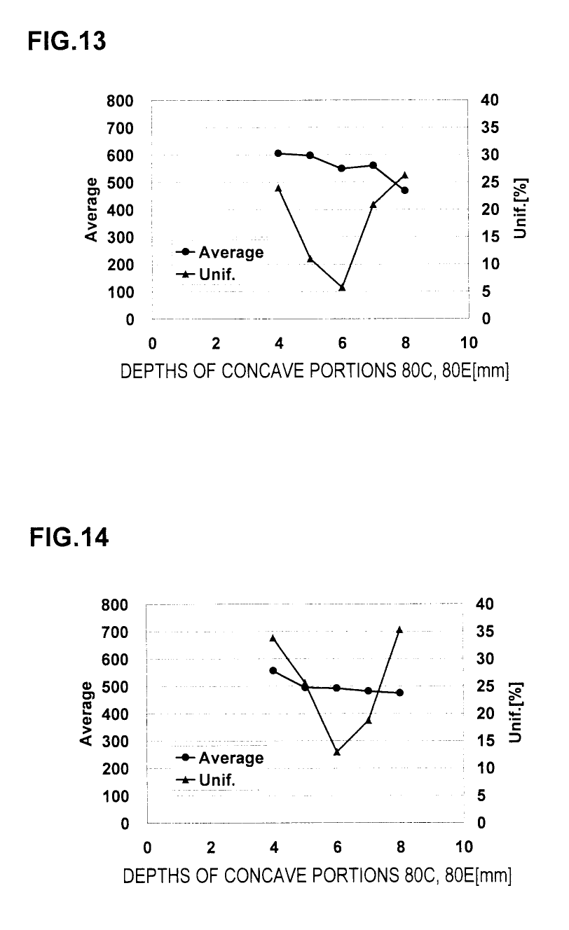

Further, the depths d of the concave portions 80c, 80e placed interior to the slots 70 are changed in a range of 4 to 8 mm and the electric field strength average (Average) and its uniformity (Unif (%)) of the respective concave portions 80a to 80g with respect to the depths d of the concave portions 80c, 80e were examined. Then, FIGS. 13 and 14 are obtained. Here, in FIG. 13, the electric field strength average (Average) and uniformity (Unif (%)) of the respective concave portions 80a to 80g were obtained from the maximum electric field strengths (Complex MagE) of the respective concave portions 80a to 80g per cycle. Further, in FIG. 14, the electric field strength average (Average) and uniformity (Unif (%)) of the respective concave portions 80a to 80g were obtained from the maximum electric field strengths (Complex MagE) at the center of the concave portions 80a to 80g per cycle. Further, the relation is made as: uniformity (Unif (%))=(maximum value of the electric field strength of the respective concave portions 80a to 80g-minimum value)/(2×electric field strength average). As a result, as shown in FIGS. 13 and 14, the maximum electric field strength in the respective concave portions 80a to 80g had the smallest uniformity when the depths d of the concave portions 80c, 80e placed interior to the slots 70 were made 6 mm and plasma was able to be generated substantially evenly on the entire lower surface of the dielectric 32.

### INDUSTRIAL APPLICABILITY

The present invention can be applied to, for example, a CVD processing and an etching processing.

1. A plasma processing apparatus performing plasma processing on a substrate, wherein
microwave is propagated into a dielectric provided on an upper surface of a processing chamber through plural slots formed on a lower surface of a waveguide and a processing gas supplied into the processing chamber is made into plasma using an electric field energy of an electromagnetic field formed on a surface of the dielectric, and
one or more plural concave portions are formed on the lower surface of the dielectric and the depth of the concave portion is changed corresponding to a distance from the slots.

2. The plasma processing apparatus according to claim 1, wherein
plural dielectrics are provided on the upper surface of the processing chamber and the one or more concave portions are formed on the lower surfaces of the respective dielectrics.

3. The plasma processing apparatus according to claim 1, wherein
on the lower surface of the dielectric, the concave portions are formed at a position close to the slots and at a position separate from the slots and the depth of the concave portion formed separately from the slot is made deeper than the depth of the concave portion formed close to the slot.

4. The plasma processing apparatus according to claim 3, wherein
the dielectric is formed in a rectangular shape having a length in a longitudinal direction longer than a wavelength of the microwave propagated in the dielectric and a length in a width direction shorter than the wavelength of the microwave propagated in the dielectric.

5. The plasma processing apparatus according to claim 4, wherein
on the lower surface of the dielectric, plural concave portions are formed as being aligned along the longitudinal direction.

6. The plasma processing apparatus according to claim 5, wherein
the dielectric is provided to cross over two slots and a concave portion having a deepest depth is formed between the two slots.

7. The plasma processing apparatus according to claim 6, wherein
the concave portion placed in the middle between the two slots has a deepest depth.

8. The plasma processing apparatus according to claim 6, wherein
between the two slots, the concave portion placed between the concave portion placed in the middle and the concave portions placed closest to the slots has a deepest depth.

9. The plasma processing apparatus according to claim 6, wherein
on the lower surface of the dielectric, among the plural concave portions formed as being aligned along the longitudinal direction, the depths of the concave portions placed at the both ends are made shallower than the depths of the concave portions placed interior to the slots.

10. The plasma processing apparatus according to claim 2, wherein
around the plural dielectrics, one, two or more gas ejecting ports supplying a processing gas into the processing chamber are provided.

11. The plasma processing apparatus according to claim 10, wherein
the gas ejecting port is provided to a supporting member supporting the plural dielectrics.

12. The plasma processing apparatus according to claim 2, wherein
around the plural dielectrics, one, two or more first gas ejecting ports supplying a first processing gas into the processing chamber and one, two or more second gas ejecting ports supplying a second processing gas into the processing chamber are provided.

13. The plasma processing apparatus according to claim 12, wherein
one of the first gas ejecting port and the second gas ejecting port is disposed lower than the other of the first gas ejecting port and the second gas ejecting port.

14. A plasma processing method performing plasma processing on a substrate, wherein
when the plasma processing is performed on the substrate by propagating microwave into a dielectric placed on an upper surface of a processing chamber through plural slots formed on a lower surface of a waveguide and making a processing gas supplied in the processing chamber into plasma using an electric field energy of an electromagnetic field formed on a surface of the dielectric, and
plural concave portions are formed on a lower surface of the dielectric and the concave portions are made to have different depths to control the plasma generation on the lower face of the dielectric.
